(19) United States
(12) Patent Application Publication
(10) Pub. No.: US 2008/0102623 A1
(43) Pub. Date: May 1, 2008

(54) SEMICONDUCTOR DEVICE MANUFACTURING METHOD

(75) Inventors: Toshiyuki HIROTA, Tokyo (JP); Motoyuki Kono, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 11/924,177

(22) Filed: Oct. 25, 2007

(30) Foreign Application Priority Data
Oct. 30, 2006 (JP) 2006-294173

(51) Int. Cl. H01L 21/4763

(52) U.S. Cl. 438/618; 257/E21.54

(57) ABSTRACT

To provide a semiconductor device manufacturing method in which, when a silicon nitride film is formed as an anti-oxidation film on bit wires formed from tungsten film, formation of tungsten nitride film, which is a cause of increased wire resistance, is suppressed, so that yields are improved compared with related arts. A semiconductor device manufacturing method includes: a dielectric film formation process of forming a dielectric film on a semiconductor substrate; a wire pattern formation process of forming a wire pattern having a tungsten film on the dielectric film; and a wire pattern covering process of depositing a silicon nitride film using Atomic Layer Deposition processing employing dichlorosilane and ammonia radicalized by plasma, and covering the wire pattern.

### BACKGROUND OF THE INVENTION

1. Field of the Invention

The present invention relates to a semiconductor device manufacturing method, and in particular related to a semiconductor device manufacturing method comprising a process of forming low-resistance metal wiring.

Priority is claimed on Japanese Patent Application No. 2006-294173, filed on Oct. 30, 2006, the contents of which are incorporated herein by reference.

2. Description of the Related Art

In semiconductor devices, tungsten (W), a high-melting-point metal, has generally been used as wiring in portions where heat resistance is required.

In semiconductor devices having multilayer wiring structures, interlayer dielectric films are formed to electrically insulate wiring layers. A silicon oxide film, formed by the CVD (Chemical Vapor Deposition) method, is used for such interlayer dielectric films.

Tungsten is easily oxidized in an oxygen atmosphere environment during formation of a silicon oxide film, so that WOₓ (tungsten oxide), having a much higher resistance than tungsten, is formed. As a result, the wiring resistance rises, and volume expansion gives rise to poor adhesion and other problems.

In order to avoid the above-described problem, instead of forming a silicon oxide film directly on the tungsten wiring, a method is used in which portions in which a tungsten layer is exposed are covered with a silicon nitride film, this silicon nitride film is caused to function as an anti-oxidation film, and the CVD method is used to form a silicon oxide film thereupon (see for example Japanese Unexamined Patent Application, First Publication No. H03-147328 (hereinafter referred to as “Patent Document 1”)).

To form the silicon nitride film as an anti-oxidation film, the low-pressure CVD method is used in which dichlorosilane (SiH₂Cl₂) and ammonia (NH₃) are used as source gases and the film is deposited in the temperature range of 630 to 680 degrees Celsius.

Below, with reference to FIG. 13 to FIG. 16, related art is described in which tungsten is used for bit wires in DRAM (Dynamic Random Access Memory), forming capacitor contact plugs between the bit wires.

First, as shown in FIG. 13, a hole is opened in the interlayer dielectric film 201, and a contact plug 202 is formed connected to, for example, the diffusion layer of a MOS (Metal Oxide Semiconductor) transistor formed below.

Next, the entire surface is covered with the interlayer dielectric film 203, and the tungsten film 204 and a silicon nitride film 205 serving as a hard mask during tungsten film machining are deposited on the interlayer dielectric film 203 by the plasma CVD method.

Next, as shown in FIG. 14, photolithography and a dry etching method are used to etch the silicon nitride film 205, using photoresist as a mask. Then, the photoresist is removed, and the silicon nitride film 205 is used as a mask to etch the tungsten film 204, forming the bit wires.

Next, as shown in FIG. 15, low-pressure CVD method is used, at a temperature of 630 to 680 degrees Celsius and with dichlorosilane and ammonia as the source gases, to form a silicon nitride film 206 as an anti-oxidation film.

Next, as shown in FIG. 16, a HDP (High Density Plasma)-CVD method is used to form an interlayer dielectric film 207, composed of a silicon oxide film, over the entire surface.

At this time, the bit wire composed of the tungsten film 204 is covered by the anti-oxidation film which is the silicon nitride film 206, and so is not directly exposed to an oxidizing atmosphere during formation of the interlayer dielectric film 207. Hence reactions resulting in tungsten oxide (WOₓ) can be suppressed, and increases in the bit wire resistance can be prevented.

Then, CMP (Chemical-Mechanical Polishing) method is used to flatten the interlayer dielectric film 207, and photolithography and a dry etching method are used to form capacitor contact holes in the interlayer dielectric film 207, expose the surface of the contact plugs 202, and form capacitor contact plugs 208.

Patent Document 1 discloses a semiconductor device manufacturing method in which a plasma nitridation method and a thermal nitridation method using lamp heating are employed to form a tungsten nitride film on the surface of the tungsten film, and the tungsten nitride film is used as an anti-oxidation film. Further, Japanese Unexamined Patent Application, First Publication No. 2002-353334 (hereinafter referred to as “Patent Document 2”) discloses a method for forming a silicon nitride film by an ALD (Atomic Layer Deposition) method, in which dichlorosilane and ammonia are supplied in alternation.

The inventors have performed experiments in search of methods for reducing the resistance of bit wires composed of tungsten films, and as a result of studying the experimental results, have found that not only tungsten oxide (WOₓ), but also silicon nitride film itself, used as an anti-oxidation film as described in relation to the Related Art, also greatly contributes to increase resistance. Below, the details of these studies are explained.

As one aspect of these studies, the correspondence relation between the wire width and the wire resistance of tungsten film 204 was investigated. As a result, the wire resistance when the wire width was reduced did not agree with the value obtained by extrapolating the wire resistance when the wire width was large. That is, it was found that the actual wire width when the wire width was reduced shows a larger increase in resistance compared with the resistance increase proportional to the reduction in wire width, and did not agree with a linear relation in accordance with a simple linear function.

The disparity between the resistance value calculated from this linear relation and the resistance value obtained in actual measurements grew more prominent as the wire width of the tungsten layer 204 was decreased, and values of: 10% higher at a wire width of 80 nm; 15% higher at a wire width of 60 nm; 24% higher at a wire width of 40 nm; and 46% higher at a wire width of 25 nm were obtained.

In order to elucidate the cause of this disparity, anti-oxidation films composed of silicon nitride film 10 nm thick were formed by low-pressure CVD method at a temperature of 650 degrees Celsius, using dichlorosilane and ammonia as source gases; bit wires composed of tungsten film 204 were covered with this anti-oxidation film, and cross-sections thereof were analyzed by TEM (Transmission Electron Microscopy) and EELS (Energy-Loss Spectroscopy).

As shown in FIG. 17, the results confirmed the formation of a tungsten nitride film 209 of thickness 3 to 4 nm at the interface between the tungsten film 204 and the silicon nitride film 206. This tungsten nitride film 209 is a conductor, but compared with tungsten the resistance value is approximately 10 times higher, leading to an increase in the overall wire resistance.

From the above-described results, it is thought that when using low-pressure CVD method at 650 degrees Celsius to deposit the silicon nitride film, the tungsten film 204 reacts with the ammonia used as a source gas and is nitrified.

From experimental results, it was also confirmed that at 550 degrees Celsius and below, the surface of the tungsten film is not nitrided even when the tungsten film is exposed to an ammonia atmosphere.

However, in low-pressure CVD methods using dichlorosilane and ammonia which have been conventionally used, it is difficult to induce a reaction at 550 degrees Celsius or below, and such methods cannot be used for deposition of silicon nitride films in semiconductor manufacturing processes.

Moreover, as is disclosed in Patent Document 2, attempts were made to form silicon nitride films by the ALD method in which film is only deposited on an underlayer surface with dichlorosilane and ammonia supplied in alternation. However, there was substantially no reaction at 550 degrees Celsius, and it was found that an adequate deposition rate could not be obtained.

Furthermore, when silicon nitride film deposition is performed using a plasma CVD method, which can be performed even at low temperatures, an overhang state occurs at the wire steps, and when forming the interlayer dielectric film 207, voids occur between adjacent patterns of the tungsten film 204. These voids cause short-circuits between contact plugs 208 that are adjacent in the depth direction in FIG. 16, so that the problem of worsened yields occurs.

### SUMMARY OF THE INVENTION

The present invention has been made in light of such circumstances, and has as an object the provision of a semiconductor device manufacturing method in which, when a silicon nitride film is formed as an anti-oxidation film on bit wires formed from tungsten film, formation of tungsten nitride film, which is a cause of increased wire resistance, is suppressed, so that yields are improved compared with related arts.

A semiconductor device manufacturing method in accordance with the present invention comprises: a dielectric film formation process of forming a dielectric film on a semiconductor substrate; a wire pattern formation process of forming a wire pattern having a tungsten film on the dielectric film; and a wire pattern covering process of depositing a silicon nitride film using Atomic Layer Deposition processing employing dichlorosilane and ammonia radicalized by plasma, and covering the wire pattern.

In the semiconductor device manufacturing method, the silicon nitride film may be formed as an anti-oxidation film of exposed side walls of the wire pattern.

In the semiconductor device manufacturing method, the wire pattern may be a polymetal structure having a tungsten film and polysilicon into which impurities have been introduced.

In the semiconductor device manufacturing method, the Atomic Layer Deposition processing may be performed at a temperature in the range 500 degrees Celsius to 550 degrees Celsius.

In the Atomic Layer Deposition processing in the semiconductor device manufacturing method, the silicon nitride film may be deposited by performing a plurality of cycles, where one cycle includes a series of processes in which nitrogen purging is performed, dichlorosilane is supplied, nitrogen purging is performed, and ammonia radicalized by a plasma-assisted process is supplied.

By means of the present invention, increases in wire resistance can be prevented, and wires composed of tungsten film, having lower wire resistance compared with the related art, can be formed. Furthermore, because increases in wire resistance can be suppressed, higher product yields compared with the related art can be attained.

### BRIEF DESCRIPTION OF THE DRAWINGS

FIG. 1 is a conceptual diagram showing the cross-sectional structure of a semiconductor device manufactured by the manufacturing methods of a first embodiment and of a second embodiment of the present invention;

FIG. 2 through FIG. 5 are conceptual diagrams showing the cross-sectional structures in each process of the semiconductor device manufacturing method of the first embodiment;

FIG. 6 through FIG. 12 are conceptual diagrams showing the cross-sectional structures in each process of the semiconductor device manufacturing method of the second embodiment; and,

FIG. 13 through FIG. 17 are conceptual diagram showing the cross-sectional structures in each process of a conventional semiconductor device manufacturing method.

### DETAILED DESCRIPTION OF THE INVENTION

### First Embodiment

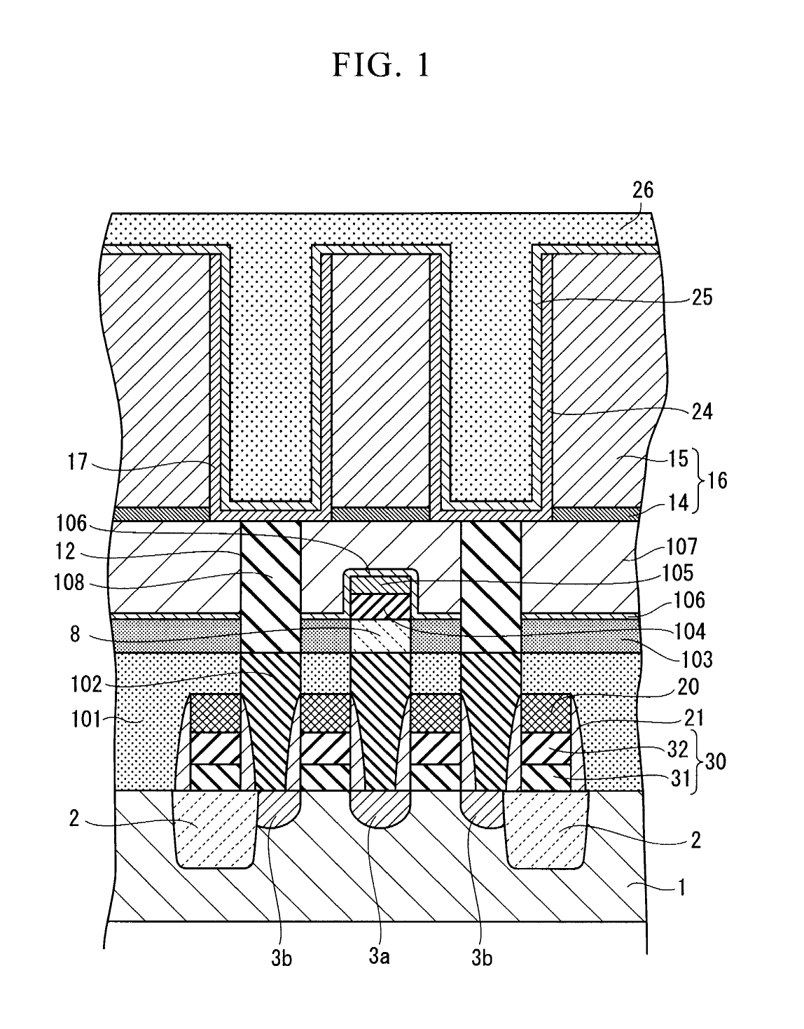

Below, the semiconductor device in accordance with a first embodiment of the present invention is explained, referring to the drawings. FIG. 1 is a conceptual diagram showing the cross-sectional structure of a semiconductor device in accordance with this embodiment.

In the drawing, the semiconductor substrate 1 is formed from a semiconductor (for example silicon) into which impurities (for example p-type (boron or similar) impurities) have been introduced to a prescribed concentration.

The device isolation region 2 is formed in a portion other than the transistor formation region of the surface of the semiconductor substrate 1 by an STI (Shallow Trench Isolation) method, to insulate and isolate transistors (selection transistors).

In a transistor formation region, a gate dielectric film (not shown) composed of a silicon oxide film is formed on the surface of the semiconductor substrate 1 by for example a thermal oxidation method.

The gate electrode 30, of a multilayer film comprising for example polysilicon film 31 and metal film 32, is formed on the gate dielectric film. As the polysilicon film 31, a doped polysilicon film formed by introducing impurities during deposition by the CVD method can be used. As the metal film 32, tungsten, tungsten silicide (WSi), or another high-melting-point metal can be used.

A cover film 20, of silicon nitride film or similar, is formed on the gate electrode 30, and sidewalls 21, of dielectric film such as silicon nitride film, are formed on the sidewalls of the gate electrode 30.

A source diffusion layer 3b is formed in a surface region of the semiconductor substrate 1, on one end of the gate electrode 30, and a drain diffusion layer 3a is formed in a surface region of the semiconductor substrate on the other end of the gate electrode 30.

In each contact hole formed in self-aligned fashion from the cover film 20 and sidewalls 21, a contact plug 102 connected to the source diffusion layer 3b or drain diffusion layer 3a is formed by means of polysilicon film with a prescribed impurity concentration.

In the trench portion formed between the contact plugs 102 is formed a first interlayer dielectric film 101. That is, each contact plug 102 is electrically insulated from the adjacent contact plug 102 by the first interlayer dielectric film 101.

Above the contact plugs 102 and above the first interlayer dielectric film 101 are formed, over the entire surface, a second interlayer dielectric film 103, silicon nitride film (Si₃N₄) 106, and third interlayer dielectric film 107.

A contact hole is formed, penetrating the second interlayer dielectric film 103, such that the upper surface of the contact plug 102 connected to the drain diffusion layer 3a is exposed.

In this contact hole, a bit line contact plug 8, composed of Ti/TiN/W metal films, is formed.

On the surface of the bit line contact plug 8 are formed a bit line 104 comprising tungsten film (metal film) and silicon nitride film 105. That is, the bit line 104 is connected to the drain diffusion layer 3a of the MOS transistor via the contact plug 102 and bit line contact plug 8. The above-described silicon nitride film 106 is formed, as sidewalls, at the sidewalls of the bit line 104.

A capacitor contact hole 12 is formed, penetrating the second interlayer dielectric film 103 and the third interlayer dielectric film 107, such that the upper surface of the contact plug 102 connected to the source diffusion layer 3b of the MOS transistor is exposed.

Within the capacitor contact hole 12 is formed a capacitor contact plug 108 composed of polysilicon, into which P (phosphorus) has been introduced as an impurity.

A fourth interlayer dielectric film 16 composed of an oxide film 15 and a stopper silicon nitride film 14 is formed over the entire surface, and a capacitor cylinder 17, forming the core of the capacitor, is formed directly above the capacitor contact plug 108.

A lower electrode 24, and an upper electrode 26 formed above the lower electrode 24 with a capacitor dielectric film 25 intervening, are formed on the base surface and side walls of the capacitor cylinder 17. The upper electrode 26 is configured from, for example, a combined layer of TiN film and W layer.

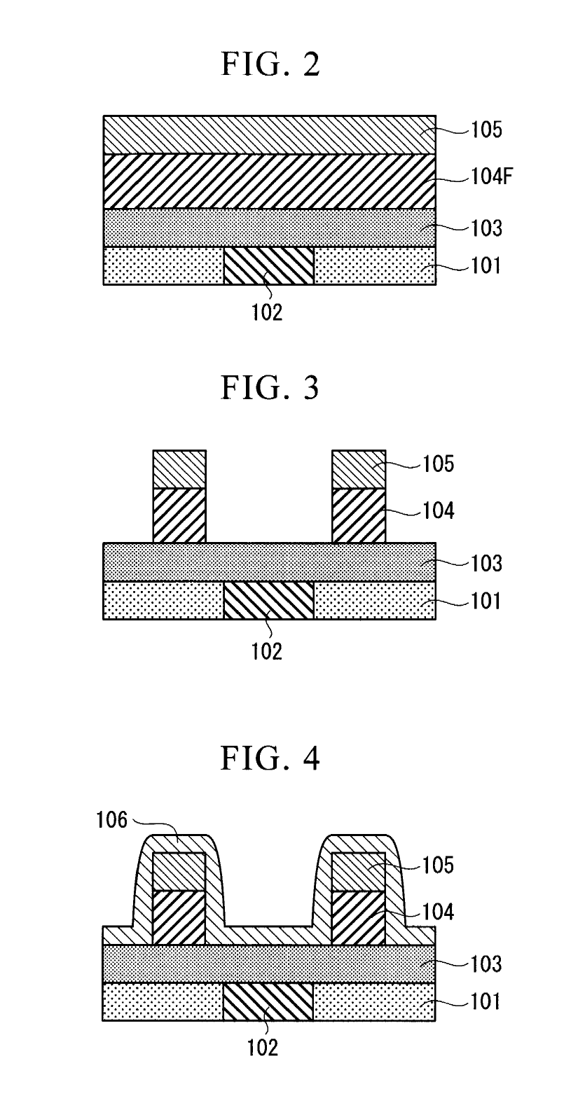

Next, FIG. 2 through FIG. 5 are used to explain processes when forming capacitor contact plugs 108 between bit lines 104 using tungsten film in the dynamic random access memory (hereafter “DRAM”) of one embodiment of the present invention. FIG. 2 through FIG. 5 are conceptual diagrams showing the cross-sectional structure of the semiconductor device in each manufacturing process of the manufacturing method of the present embodiment.

First, each of the constituent elements of a MOS transistor, shown in FIG. 1, is formed. That is, the device isolation regions 2, source diffusion layer 3b, and drain diffusion layer 3a are formed in the semiconductor substrate 1, and in addition the gate electrode 30, sidewalls 21, and cover dielectric film 20 are formed on the semiconductor substrate 1.

Then, as shown in FIG. 2, a plasma CVD (Chemical Vapor Deposition) method is used to form a first interlayer dielectric film 101, composed of a silicon oxide film, over the entire surface of the MOS transistor to a thickness of 450 nm, and after reflow processing, CMP (Chemical-Mechanical Polishing) method is used to flatten the surface.

Next, photoresist is applied onto the flattened first interlayer dielectric film 101, and photolithography is used to form a resist pattern of openings for the contact plugs 102; this resist pattern is used as a mask to perform anisotropic etching, to form contact holes for the contact plugs 102.

Then, after removing the resist pattern, CVD method is used to deposit polysilicon, into which impurities have been introduced, over the entire surface. It should be noted that the polysilicon is formed to a thickness sufficient to fill the contact holes with polysilicon. The impurity concentration in the polysilicon is from 1.0×10²⁰ to 4.5×10²⁰ atoms/cm³.

Then, after performing etching-back by means of dry etching using a chlorine plasma gas, CMP method is used to flatten the surface, and the silicon film on the first interlayer dielectric film 101 is removed, while the polysilicon filling the contact holes is left, to form the contact plugs 102. A contact plug 102 connects the wiring pattern of the bit line 104 composed of tungsten film shown in FIG. 1, with the diffusion layer 3a. A contact plug 102 also connects the capacitor contact plug 108 with the diffusion layer 3b. Although not shown, contact holes are formed in the second interlayer dielectric film 103 using photolithography and anisotropic etching, and after depositing in order multilayer metal film of Ti/TiN/W using CVD method over the entire surface, CMP is used to perform flattening, to form the bit line contact plug 8 shown in FIG. 1.

Next, plasma CVD method is used to deposit the second interlayer dielectric film 103 composed of silicon oxide film over the entire surface to a thickness of 200 nm, and a tungsten film 104F of thickness 50 nm is deposited by a sputtering method onto the second interlayer dielectric film 103 in order to form the bit line 104 (see FIG. 2). At this time, a tungsten nitride film or titanium nitride film of thickness 5 nm to 10 nm may be deposited between the tungsten film 104F and the second interlayer dielectric film 103, intervening as an adhesion layer between the tungsten film 104F and the second interlayer dielectric film 103.

Then, plasma CVD method is used to deposit a silicon nitride film 105 on the tungsten film 104F, as a hard mask for use in patterning the bit line 104.

Photoresist is applied onto this silicon nitride film 105, and photolithography is used to form a resist pattern in order to form a bit line 104 from the deposited tungsten film 104F; this resist pattern is used as a mask to etch the silicon nitride film 105, by anisotropic etching or similar, to form a shape corresponding to a bit line pattern.

Next, the photoresist is removed, and as shown in FIG. 3, anisotropic etching is performed using the pattern of the silicon nitride film 105 as a hard mask, forming the tungsten film 104F into a pattern of width 25 nm as a pattern of the bit line 104. At this time, the side walls (that is, the tungsten film) of the bit line 104 are exposed.

Then, as shown in FIG. 4, Si₃N₄ is deposited by a plasma-assisted ALD method using dichlorosilane and ammonia as source gases, to form a silicon nitride film 106 over the entire surface as an anti-oxidation film in the subsequent formation of the third interlayer dielectric film 107 (in particular, as an anti-oxidation film of the tungsten film exposed at the side walls of the bit line 104). By this means, the side faces of the bit line 104 at which the tungsten film is exposed are covered by the silicon nitride film 106 acting as an anti-oxidation film.

To explain in further detail, while inserting a purging step using nitrogen, ammonia radicalized by plasma and dichlorosilane at a temperature of 500 to 550 degrees Celsius are supplied in alternation to a reaction chamber in a vertical batch-type plasma-assisted ALD apparatus, to deposit the silicon nitride film 106. That is, a single cycle consisted of purging with nitrogen is performed for 7 seconds, dichlorosilane is supplied for 7 seconds at 120 SCCM (standard cc/min), purging with nitrogen is performed for 7 seconds, and supplying plasma-assisted ammonia at 6000 SCCM for 9 seconds (for a total of 30 seconds); a plurality of such cycles were performed to deposit the silicon nitride film 106 to a prescribed thickness.

In the above-described film formation processing, film could be deposited to a thickness of 0.08 nm in a single cycle; when one cycle was executed in 30 seconds, the effective growth rate was then 0.16 nm/min.

With the aim of forming to a thickness of 10 nm in a mass-production process, the silicon nitride film 106 in this embodiment serving as an anti-oxidation film of tungsten, and taking into consideration the loading effect of products with large surface area, deposition was performed at settings such that the thickness on a wafer for film thickness monitoring was 12 nm (150 cycles).

As already described above, it is clear from experimental results that if the ambient temperature is 550 degrees Celsius or lower when depositing the silicon nitride film 106, then the surface of the tungsten film at the sidewalls of the bit line 104 is not nitrided even when exposed to an ammonia atmosphere, so that there is no increase in the wire resistance of the wire pattern of the bit line 104. The cross-sections of bit lines 104 were observed by TEM and EELS, but substantially no tungsten nitride (WN) film could be observed at the interface between the tungsten film exposed at the sidewalls of the bit line 104 and the silicon nitride film 106.

Furthermore, because the silicon nitride film 106 is deposited using a plasma-assisted ALD apparatus, the silicon nitride film 105 is deposited with good coverage even on the side faces of the bit line 104, at which the tungsten film is exposed.

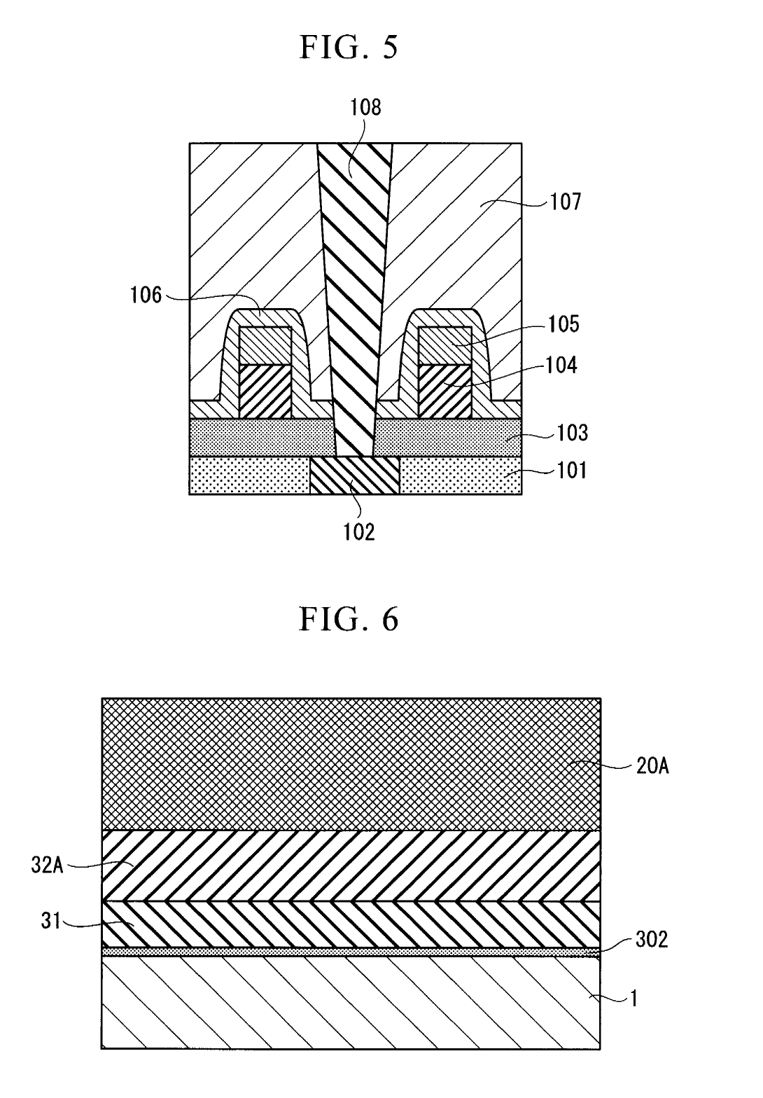

As shown in FIG. 5, after depositing a silicon oxide film serving as the third interlayer dielectric film 107 over the entire surface of the silicon nitride film 106 by HDP-CVD, CMP method was used to flatten the surface.

When depositing this third interlayer dielectric film 107, the side faces of the bit line 104 at which the tungsten film is exposed are protected from the oxidizing atmosphere by the silicon nitride film 106, which is an anti-oxidation film, so that oxidation of the tungsten film exposed at the bit line 104 is prevented. Hence when depositing the third interlayer dielectric film 107, there is no longer an increase in the wire resistance of the wire pattern of the bit line 104.

Next, after flattening the third interlayer dielectric film 107, photoresist is applied, and photolithography is used to form a resist pattern at the upper portion of the contact plug 108, to be used in creating the contact hole to be formed in the third interlayer dielectric film 107. Then, using this resist pattern as a mask, anisotropic etching of the third interlayer dielectric film 107 is performed, to form a capacitor contact hole 12 through which the upper face of the contact plug 108 is exposed.

Then CVD method is used to deposit polysilicon, with impurities introduced, over the entire surface. This polysilicon is deposited to a thickness sufficient that the capacitor contact hole 12 is filled with polysilicon.

After deposition of the polysilicon, and after etching back by dry etching using a chlorine plasma gas, CMP is performed to remove the polysilicon on the third interlayer dielectric film 107, leaving the polysilicon in the capacitor contact hole 12, to form the capacitor contact plug 108.

After forming the capacitor contact plug 108, a stopper silicon nitride film 14 is formed by LP (Low-Pressure) CVD over the entire surface as an oxide film etching stopper, to be used when forming a capacitor cylinder 17 in which capacitor described below is formed. Then, plasma CVD is used to form an oxide film 15 comprised of silicon nitride film of thickness 3000 nm over the entire surface, to serve as the core of the capacitor cylinder in which a cylinder-type capacitor is formed. The stopper silicon nitride film 14 and oxide film 15 formed in order in this way serve as the fourth interlayer dielectric film 16.

Then, photoresist is applied and photolithography is performed to form a resist pattern used in creating the capacitor cylinder 17 (cylinder hole) in which capacitor is formed.

Thereafter this resist pattern is used as a mask in anisotropic etching, to form the capacitor cylinder 17 (cylinder hole) penetrating the oxide film 15 that forms the fourth interlayer dielectric film 16 and extending to the stopper silicon nitride film 14 above the capacitor contact plug 108.

After removing the resist pattern used to form the capacitor cylinder 17, the exposed stopper silicon nitride film 14 is etched by anisotropic etching or another method to expose the upper face of the contact plug 108, to form the capacitor cylinder 17 penetrating the fourth interlayer dielectric film 16.

Next, prior to forming an amorphous silicon film to become the lower electrode of the capacitor, wet preprocessing using a solution containing hydrofluoric acid is performed on the exposed face of the contact plug 108 after etching of the stopper silicon nitride film 14, to remove the natural oxidation film formed on the exposed face of the contact plug 108, in order to suppress increases in resistance at the interface with the contact plug 108.

After removing the natural oxidation film, a conductive film which is to become the lower electrode is formed on the entire surface, including the side faces and bottom face of the capacitor cylinder 17. For example, CVD method is used to deposit in order titanium and titanium nitride over the entire surface, to a thickness of 30 nm for the two-layer TiN/Ti film.

Next, photoresist is applied, and after leaving photoresist only in the capacitor cylinder 17, the portions other than the capacitor cylinder 17 (that is, the conductive film of TiN/Ti on the surface of the fourth interlayer dielectric film 15) are removed by etching. Then, the photoresist is removed, to form the lower electrode 24 of the capacitor, the lower electrode 24 comprised of the conductive film.

Next, the surface of this conductive film is nitrided by means of heat treatment in an N₂ atmosphere, to serve as a stopper which suppresses oxidation of the conductive film when oxidizing the tantalum oxide film to serve as the capacitor dielectric film 25.

Then, CVD method is performed, with tantalum pentaethoxide as a raw material and using oxygen as an oxidizing agent, to form a tantalum oxide film 8 nm thick on the lower electrode 24, as the capacitor dielectric film 25 serving as the capacitor dielectric film (that is, dielectric film). Moreover, in order to improve the insulating performance of this tantalum oxide film serving as the capacitor dielectric film 25, heat treatment is performed at 750 degrees Celsius in an oxidizing atmosphere.

Thereafter, a conductive layer (for example, a laminate of a titanium nitride film and a tungsten film) to serve as the upper electrode 26 is formed in succession by CVD method.

In the above-described processes, the capacitor dielectric film is not limited to a tantalum oxide film, and for example an aluminum oxide film, a hafnium oxide film, a zirconium oxide film, or another single metal oxide film, or a laminate of these, can be used.

Compared with a case in which the conventional LP-CVD method (in which a nitride film is formed on the exposed tungsten film at a treatment temperature of 630 degrees Celsius) is used for formation of a nitride film as the anti-oxidation film, in the above-described process, nitridation of the tungsten film exposed at the bit line 104 is suppressed, and actual measurements have confirmed that the wire resistance of the wire pattern of the bit line 104 is reduced by approximately 30%. Through this reduction of the wire resistance of the bit line 104, there is the advantageous result that the quantity of manufactured products which are classified as fast-operation products is increased.

Moreover, there is no occurrence of worsening of pattern shape, such as the occurrence of voids between bit lines 104, nor are there problems such as short-circuits between bit lines 104, and there is the further advantageous result that yields in the processes are equal to or higher than those when using the conventional LP-CVD method.

Furthermore, when using a plasma-assisted ALD apparatus to form the silicon nitride film 106 which covers the bit line 104, film formation was performed at 450 degrees Celsius, but no reduction in wire resistance of the bit line 104 was observed compared with the case of film formation at 500 degrees Celsius.

On the other hand, a silicon nitride film 106 deposited at 450 degrees Celsius was confirmed to be of poorer film quality due to a higher etching rate, compared with a film formed at 500 degrees Celsius. That is, in the process of using dilute HF (hydrofluoric acid) to clean the interface between the contact plug 102 and the capacitor contact plug 108, the silicon nitride film 106 is etched, and short-circuits between the bit line 104 and contact plugs 108 were detected.

Hence when using a plasma-assisted ALD apparatus to deposit the silicon nitride film 106 for use as an anti-oxidation film to suppress oxidation, it is preferable that processing be performed at a temperature between 500 and 550 degrees Celsius.

As explained above, according to the present embodiment, after formation of a fine wire of width 80 nm or less from a tungsten film and before formation of an interlayer dielectric film of silicon oxide, a silicon nitride film is formed as an anti-oxidation film by an ALD method using plasmified ammonia in a plasma-assisted process, in the temperature range 500 to 550 degrees Celsius in which a tungsten nitride film is not formed. By this means, increases in wire resistance can be prevented, and wire composed of tungsten film, having a low wire resistance compared with cases of the related art, can be formed. Moreover, increases in wire resistance can be suppressed, and so high product yields compared with the related art can be achieved.

### Second Embodiment

The present invention can be similarly applied to cases in which tungsten is used not only in DRAM bit lines, as described in the first embodiment, but also as the gate electrodes 30 (word lines) formed of polymetal gates as shown in FIG. 1. Because the structure of the semiconductor device in the second embodiment is similar to that of the first embodiment, in the following only fabrication of gate electrodes 30, which differs from that in the first embodiment, is explained.

Below, the method of formation of gate electrodes 30 in DRAM of the present embodiment is explained referring to FIG. 6 through FIG. 12. FIG. 6 through FIG. 12 are conceptual diagrams showing cross-sectional structures of the semiconductor device in each process of the manufacturing method of the present embodiment.

After forming the device isolation film (not shown) in the semiconductor substrate 1, a gate oxide film 302 composed of silicon oxide film is formed by thermal oxidation in an oxygen atmosphere, as shown in FIG. 6.

The CVD method is used to form a polysilicon film 31 with N-type impurities introduced, on this gate oxide film 302, using monosilane (SiH₄) and phosphine (PH₃) as source gases; a tungsten film 32A is further deposited on the polysilicon film 31 by sputtering. At this time, either a tungsten nitride film or a titanium nitride film, or a composite film comprising both metal films, may be inserted between the tungsten film 32A and the polysilicon film 31 as an adhesion layer.

Then, the CVD method is used to form a silicon nitride film 20A on the tungsten film 32A as an interlayer dielectric film.

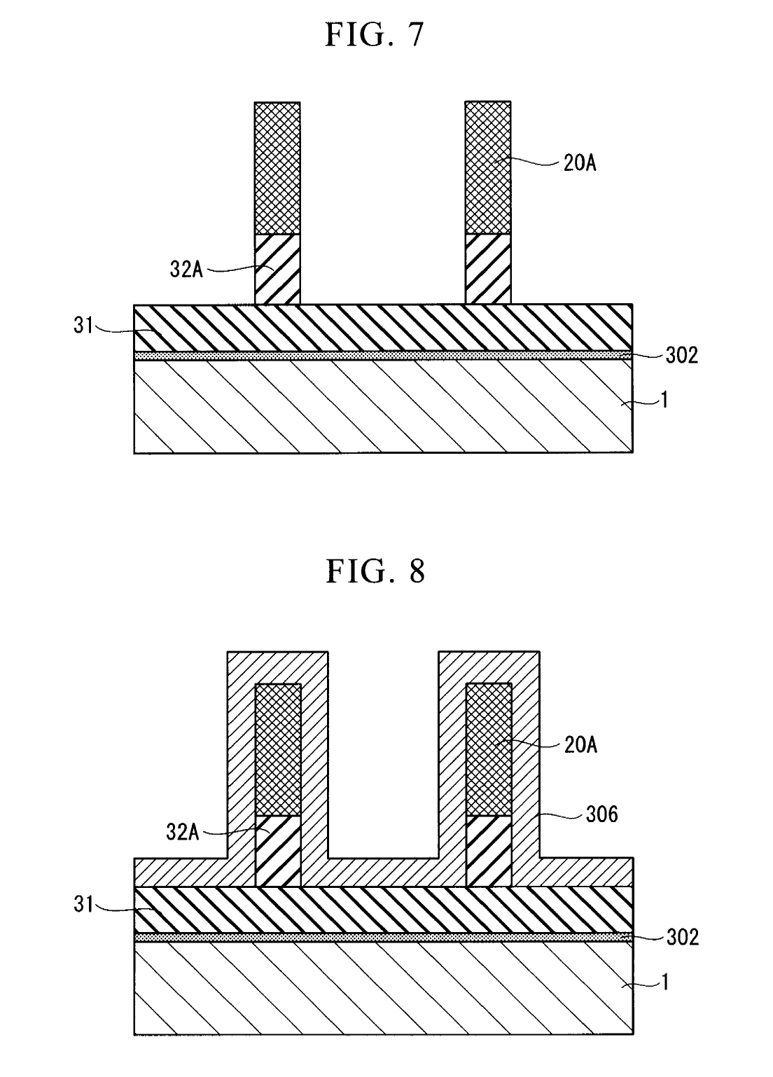

Next, photoresist is applied onto the silicon nitride film 20A and photolithography is used to form a resist pattern in order to form the gate electrode; this resist pattern is then used as a mask to perform etching of the silicon nitride film 20A and tungsten film 32A, to form a gate electrode pattern as shown in FIG. 7. At this time, when a tungsten nitride film or titanium nitride film intervenes as an adhesion layer between the tungsten film 32A and the polysilicon film 31, this adhesion layer is also etched and patterned.

Then, as shown in FIG. 8, the plasma-assisted ALD method for deposition of silicon nitride film by a plasma-assisted ALD apparatus is used, as in the first embodiment, to form a silicon nitride film 306, at a temperature of 500 to 550 degrees Celsius, to a thickness of 11 nm over the entire surface, as an oxide film protection layer to cover the exposed side walls of the tungsten film 32A.

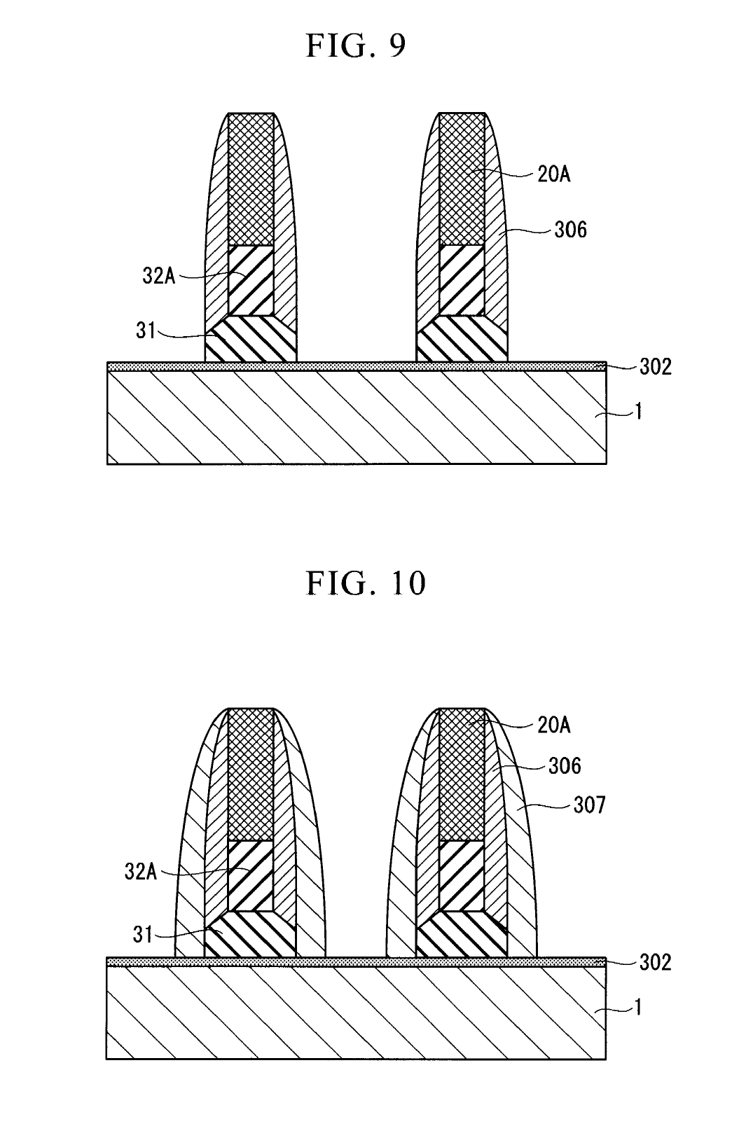

After forming the silicon nitride film 306, anisotropic etching is used for etching-back, and silicon nitride film 306 is left as side walls at the side walls of the silicon nitride film 20A and tungsten film 32A, as shown in FIG. 9.

Then, using the silicon nitride film 20A and the silicon nitride film 306 in the form of side walls as a mask, anisotropic etching is performed to pattern the polysilicon film 31. At this time, the side walls of the polysilicon 31 are exposed as shown in FIG. 9, but the side walls of the tungsten film 32A are covered by the silicon nitride film 306, and are protected from oxidation.

Next, the exposed side wall portions of the polysilicon 31 are subjected to thermal oxidation to grow a silicon oxide film of thickness 2.0 nm in an oxygen atmosphere (that is, selective oxidation of the side wall portions of the polysilicon 31 occurs), and in order to form the source and drain diffusion layers (not shown; corresponding to the diffusion layer 3b and diffusion layer 3a in FIG. 1 respectively), ion implantation is performed to introduce impurities into the semiconductor substrate 1.

Then, as shown in FIG. 10, plasma CVD is used to deposit silicon nitride film 307 over the entire surface, and normal dry etching (for example, anisotropic etching) is used to perform etch-back, covering the side walls of the gate portion, and forming side walls of silicon nitride film 307.

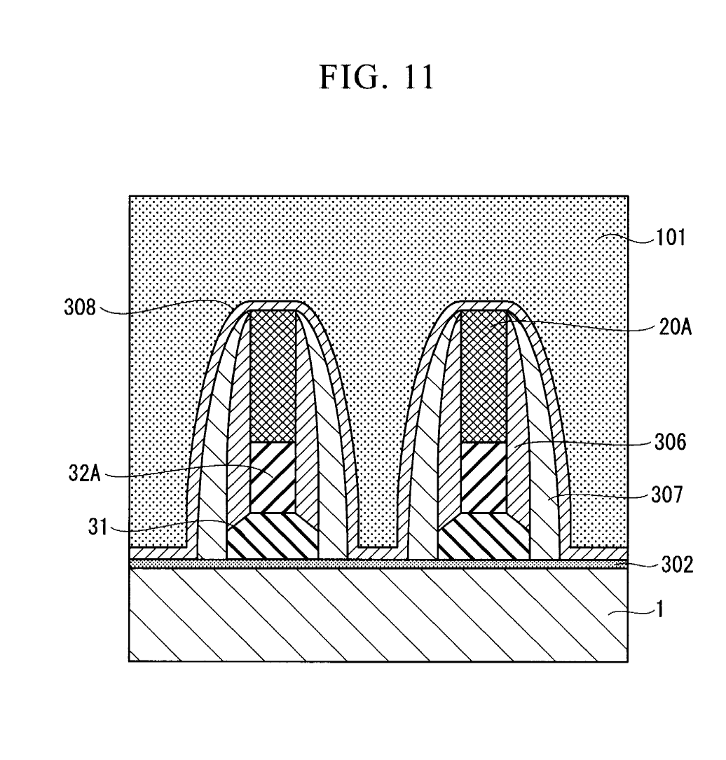

Next, as shown in FIG. 11, the LP-CVD method is used to deposit silicon nitride film 308 to a thickness of 7 nm over the entire surface, after which SA (Sub-Atmospheric)-CVD is used to form the first interlayer dielectric film 101 over the entire surface, from gas materials including O₃ (ozone), TEOS (Tetra-Ethyl Ortho Silicate), TEB (Triethyl Borate), and TEPO (Triethyl Phosphate).

Then, heat treatment in a steam atmosphere at for example 750 degrees Celsius is performed, the first interlayer dielectric film 101 is reflowed and wettability is improved, and by this means the areas between gates are buried.

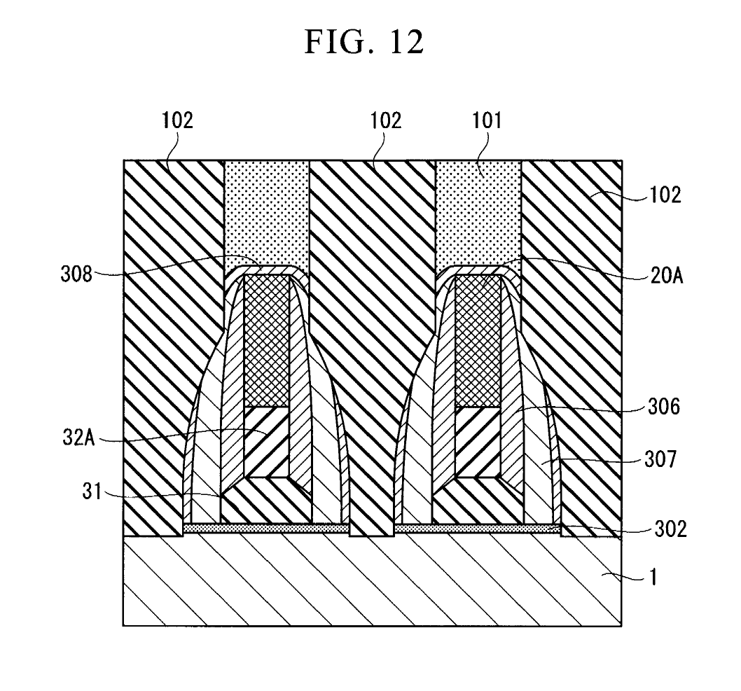

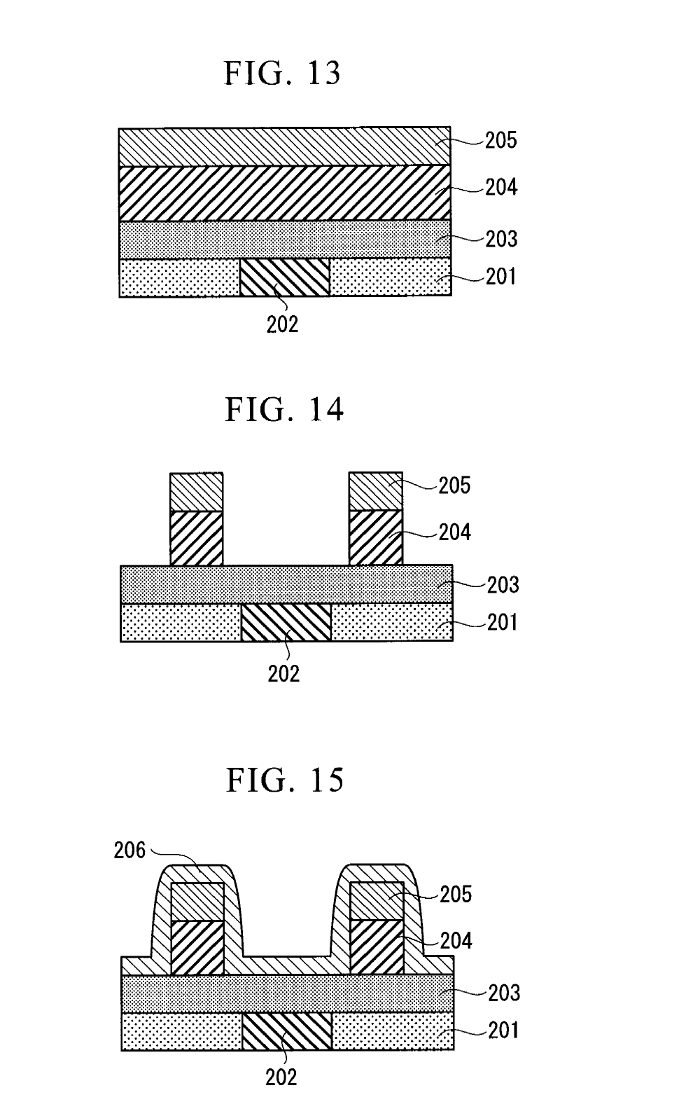

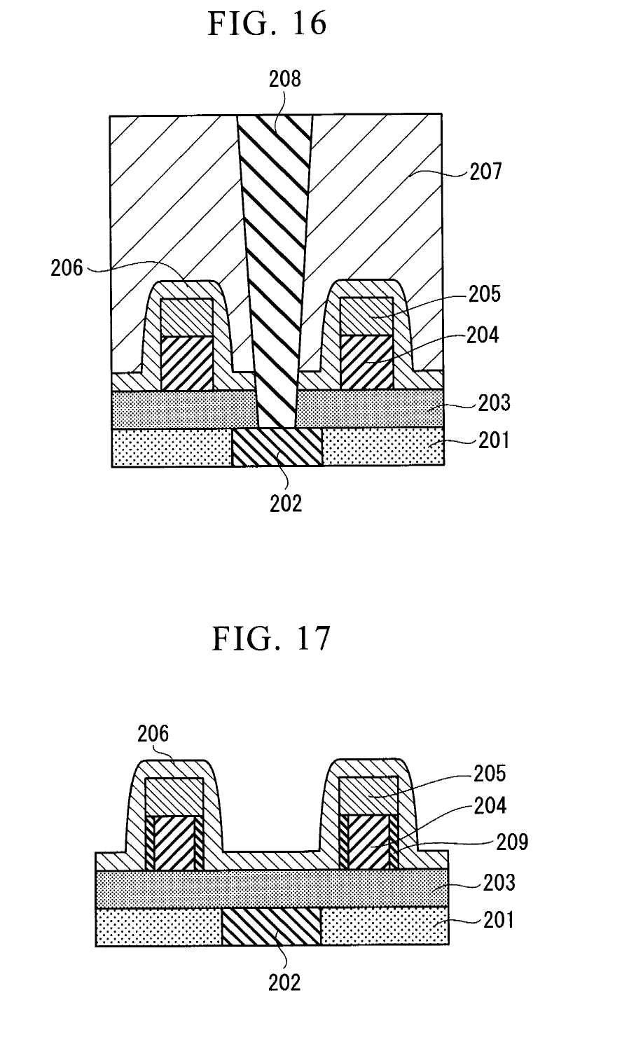

Next, as shown in FIG. 12, photoresist is applied, photolithography is used to form resist patterns for contact hole formation, and contact holes are formed between gate electrodes 30 by SAC (self-aligned contact) with each of the diffusion layers 3a and 3b.

Then, similarly to the first embodiment, polysilicon with impurities introduced is deposited over the entire surface, and etching-back and CMP are performed to form contact plugs 102.

Subsequent steps in the manufacturing method, including formation of the second interlayer dielectric film 103, are similar to those of the first embodiment, and so an explanation is omitted.

Compared with cases in which a silicon nitride film 306 is formed using LP-CVD at 680 degrees Celsius as in the related art, by forming word lines as described above, the wire resistance of gate electrodes 30 (word lines) could be reduced by 18% when the wire width of the tungsten film 32A was 45 nm.

While preferred embodiments of the present invention have been described and illustrated above, it should be understood that these are exemplary of the present invention and are not to be considered as limiting. Additions, omissions, substitutions, and other modifications can be made without departing from the gist or scope of the present invention. Accordingly, the present invention is not to be considered as being limited by the foregoing description, and is only limited by the scope of the appended claims.

What is claimed is:

1. A semiconductor device manufacturing method, comprising:
a dielectric film formation process of forming a dielectric film on a semiconductor substrate;
a wire pattern formation process of forming a wire pattern having a tungsten film on the dielectric film; and
a wire pattern covering process of depositing a silicon nitride film using Atomic Layer Deposition processing employing dichlorosilane and ammonia radicalized by plasma, and covering the wire pattern.

2. The method as recited in claim 1, wherein the silicon nitride film is formed as an anti-oxidation film of exposed side walls of the wire pattern.

3. The method as recited in claim 1, wherein the wire pattern is a polymetal structure having a tungsten film and polysilicon into which impurities have been introduced.

4. The method as recited in claim 1, wherein the Atomic Layer Deposition processing is performed at a temperature in the range 500 degrees Celsius to 550 degrees Celsius.

5. The method as recited in claim 1, wherein, in the Atomic Layer Deposition processing, the silicon nitride film is deposited by performing a plurality of cycles, where one cycle includes a series of processes in which nitrogen purging is performed, dichlorosilane is supplied, nitrogen purging is performed, and ammonia radicalized by a plasma-assisted process is supplied.
